(19) United States
(12) Patent Application Publication
(10) Pub. No.: US 2006/0061840 A1
(43) Pub. Date: Mar. 23, 2006

(54) Image processing apparatus, its calibration method, and image processing method

(75) Inventor: Yoichi Kashibuchi, Tokyo (JP)

Correspondence Address: FITZPATRICK CELLA HARPER & SCINTO, 30 ROCKEFELLER PLAZA, NEW YORK, NY, 10112, US

(73) Assignee: CANON KABUSHKI KAISHA, Tokyo (JP)

(21) Appl. No.: 11/229,801

(22) Filed: Sep. 20, 2005

(30) Foreign Application Priority Data
Sep. 22, 2004 (JP) 2004-275030 (PAT.

(51) Int. Cl. G03F 3/08

(52) U.S. Cl. 358/518

(57) ABSTRACT

A stable, unicolor intermediate density region in a four-color system is defined by mixing dark and light color recording materials in a six-color system. For this reason, a calibration for the four-color system cannot correct density variations, and a pseudo-contour due to discontinuity of tones is produced in a transition region from the light color recording materials to dark color recording materials included in the intermediate density region, thus considerably deteriorating image quality. The tone characteristics of respective colors are obtained from a patch pattern of respective color recording materials, and a tone correction table used to correct the tones of the respective colors is created on the basis of the tone characteristics of the respective colors. The tone characteristics of primary colors calculated from the tone characteristics of the respective colors with reference to a basic color density characteristic table indicating the density characteristics when the dark and light color recording materials are mixed. A basic color density correction table used to correct the tone characteristics of the primary colors is created with reference to the basic color density characteristic table and the density correction table.

### FIELD OF THE INVENTION

The present invention relates to an image processing apparatus, its calibration method, and an image processing method and, more particularly, to calibration and image processing of an image processing apparatus which uses dark and light color recording materials which have an identical hue value but different lightness values.

### BACKGROUND OF THE INVENTION

In an electrophotographic image forming apparatus, density correction (calibration) required to remove tint variations due to aging of densities (density variations) is executed in the following two stages. Initially, a test pattern is formed in the apparatus, the densities of the test pattern are measured using a sensor in the apparatus, and a transfer voltage is adjusted so that a maximum density (solid density) assumes a prescribed density value. Next, a test pattern including a halftone pattern is printed on a print sheet, the densities of the test pattern are measured using a device such as a scanner or the like to obtain the density characteristics of the halftone pattern, and a density correction table used to correct the obtained density characteristics to prescribed ones is prepared.

In order to attain high image quality, an electrophotographic image forming apparatus which uses dark and light color recording materials having an identical hue value but different lightness values has been examined. Dark color recording materials included in the dark and light color recording materials are cyan (C), magenta (M), yellow (Y), and black (K). Light color recording materials are light cyan (LC) and light magenta (LM). That is, this image forming apparatus aims at improving image quality using a six-color system which uses two colors of light color recording materials together with the four basic colors of dark color recording materials. Note that since the electrophotographic image forming apparatus uses toners as color recording materials, the color recording materials of respective colors will be referred to as toners hereinafter.

The calibration of the image forming apparatus using dark and light toners (to be referred to as “six-color system” hereinafter) is done by adjusting transfer voltages and preparing density correction tables for respective dark and light toners as in an image forming apparatus using toners of the four basic colors (to be referred to as “four-color system” hereinafter).

Correction of the maximum density by adjustment of the transfer voltage is analog correction, and errors readily occur, i.e., the maximum density is often too much or too little with respect to the prescribed density value. In case of the four-color system, such excess or deficiency of the maximum density poses a problem in a high density part, and the influence on image quality is relatively small. However, since the six-color system uses only light toners within a low density level range of an input image signal, and begins to use dark toners when the input image signal reaches a reference density level, the maximum density of light toners corresponds to an intermediate density part. Therefore, an excess or deficiency of the maximum density of the light toners brings about density variations in an intermediate density region, and causes discontinuous changes of tones of the basic colors in a density region where the dark toners begin to use. Note that the color of one color recording material or that formed by a pair of dark and light color recording materials which form colors with an identical hue value but different lightness values will be referred to as a “basic color” hereinafter.

In this manner, in the unicolor intermediate density region which is stable in the four-color system, the dark and light toners are mixed in the six-color system, and density variations cannot be corrected by the aforementioned calibration. A pseudo-contour due to discontinuity of tones is produced in a transition region from the light toners to dark toners included in the intermediate density region, thus considerably deteriorating image quality.

As a method of preventing the density variations and discontinuity of tones of the intermediate density region in the calibration of the six-color system, a test chart formed by mixing the dark and light toners is output for each execution of calibration, and the ratio of dark and light toners which express the basic colors is changed. However, this method requires a huge number of test charts, thus increasing the load and cost on the user.

Japanese Patent Laid-Open No. 2001-191589 discloses the following technique. That is, in order to always print an image in an optimal condition by a printer using C, M, Y, K dark inks and LC and LM light inks even when the printer characteristics have changed, the user selects a color separation table of dark and light inks, which is prepared in advance in correspondence with the printer characteristics upon printing.

### SUMMARY OF THE INVENTION

The first aspect of the present invention discloses a method of calibrating an image processing apparatus using dark and light color recording materials which have a similar hue value but different lightness values, the method comprising the steps of: obtaining tone characteristics of respective colors from a patch pattern of respective color recording materials; creating a density correction table for correcting the tone character of basic color generated by referring to the tone correction tables, and a character table, wherein each table indicates a density character of mixture colors mixed the dark and light color recording materials, wherein the tone character of the basic colors, which include a primary color formed by the dark color recording material, a primary color formed by the light color recording material, and the mixture colors, are calculated by referring to the character tables.

The second aspect of the present invention discloses a method comprising the step of applying color processing to color signals corresponding to the color recording materials using the density correction table and the tone correction table.

According to the present invention, a calibration method suited to an image processing apparatus which uses dark and light color recording materials which have the same hue values but different lightness values is provided. Furthermore, density variations in an intermediate density region can be prevented by a correction table obtained by that calibration method.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a block diagram showing the arrangement of an image forming apparatus according to the first embodiment of the present invention;

FIG. 2 is a view for explaining a color conversion table;

FIG. 3 shows a state wherein density levels before and after color conversion of a cyan region as a basic color are extracted from the color conversion table;

FIG. 4 is a chart for explaining color processing executed by an image processor;

FIG. 5 shows a tone patch pattern used to create a density correction table;

FIG. 6 shows a mixed patch pattern used to create a basic color density characteristic table;

FIG. 7 shows a basic color density characteristic table indicating the relationship between the mixed ratios and density values of dark and light toners;

FIG. 8 shows equal density curves obtained in 0.4-density value increments from the basic color density characteristic table using linear interpolation;

FIG. 9 is a flowchart for explaining calibration of a printer;

FIG. 10 is a flowchart showing details of density correction;

FIGS. 11A and 11B show examples of the density characteristics and density correction table of dark toners;

FIGS. 12A to 13B show examples of the density characteristics and density correction table of light toners;

FIG. 14 is a flowchart showing details of basic color density correction;

FIGS. 15 to 17 show examples of tone characteristics of dark and light toners in a primary color region, those of the whole primary colors reproduced by the dark and light toners, and prescribed primary color tone characteristics;

FIG. 18 shows an example of a basic color density table created based on basic color density correction;

FIG. 19 is a chart for explaining color processing executed by an image processor of the second embodiment;

FIG. 20 is a flowchart for explaining calibration of a printer according to the second embodiment of the present invention; and

FIG. 21 shows an example of a density correction table integrated with a basic color density correction table.

### DETAILED DESCRIPTION OF THE PREFERRED EMBODIMENTS

Image processing according to preferred embodiments of the present invention will be described in detail hereinafter with reference to the accompanying drawings.

### First Embodiment

[Apparatus Arrangement]

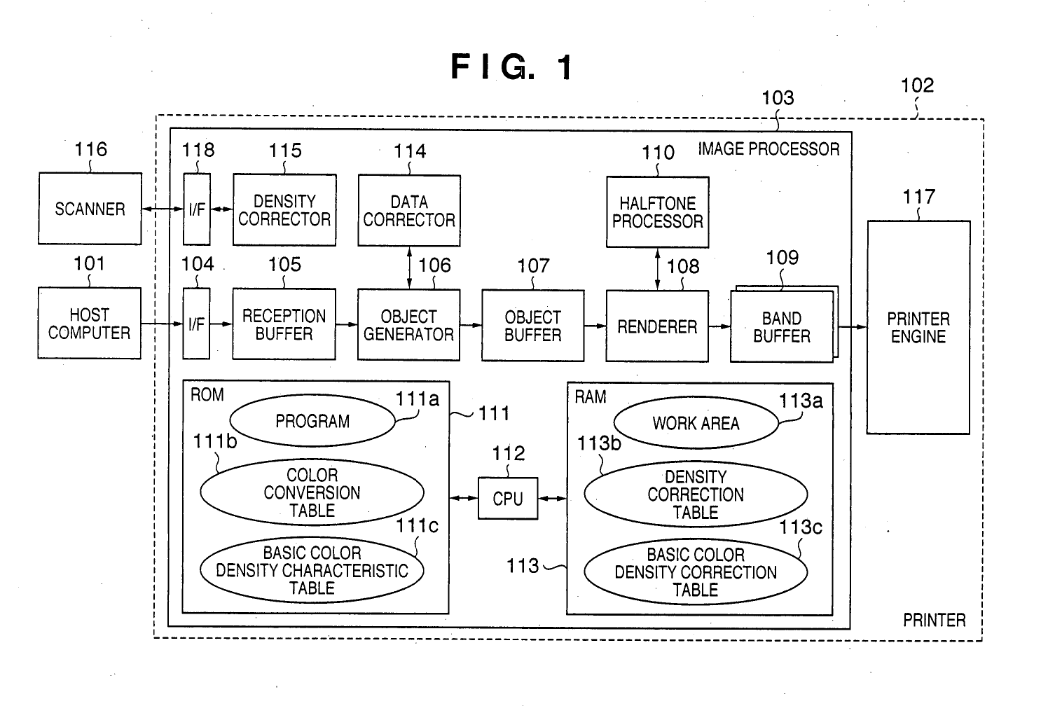

FIG. 1 is a block diagram showing the arrangement of an image forming apparatus (to be referred to as a “printer” hereinafter) of the first embodiment.

A host computer 101 outputs, to a printer 102, print information which indicates color data, text data, graphics data, image data, the number of copies to be printed, and the like and is required to execute print processing. A scanner 116 scans a patch pattern (to be described later) and outputs the scanned image data to the printer 102.

The printer 102 is roughly classified into an image processor 103 and a printer engine 117 which forms an image on the basis of an image signal output from the image processor 103.

A CPU 112 of the image processor 103 makes various kinds of processing and decision, and controls components (to be described later) of the-image processor 103 in accordance with programs stored in a ROM 111. The ROM 111 stores a color conversion table 111b, basic color density characteristic table 111c, and the like (to be described later) in addition to a program 111a for processing and control (to be described later). A RAM 113 is assigned areas for storing a density correction table 113b and basic color density correction table 113c (to be described later) in addition to a work area 113a that stores programs required when the CPU 112 makes various kinds of processing, decision and control, data, status, and the like.

Print information output from the host computer 101 is received by an I/F 104 as, e.g., a network interface or a serial bus interface (e.g., USB (Universal Serial Bus), IEEE1394, or the like) of the image processor 103, and is held in a reception buffer 105. An object generator 106 reads out the print information from the reception buffer 105, converts information such as color data, text data, graphics data, image data, and the like into intermediate information (to be referred to as “object” hereinafter), and stores converted object data in an object buffer 107.

Upon converting the print information into object data, the object generator 106 color-separates object data into color component data C, M, Y, K; LC, and LM of density levels corresponding to six color toners with reference to the color conversion table 111b. Furthermore, the object generator 106 supplies data that pertain to colors such as a gray level setting, color level setting, multi-valued image, and the like of the print information to a data corrector 114, and controls it to execute density level correction using the basic color density correction table 113c and gamma correction using the density correction table 113b (to be described later).

A renderer 108 reads out object data from the object buffer 107, and renders a bitmap image on a band buffer 109 for respective bands and color components. In this case, a halftone processor 110 executes halftone processing to drop the number of tones of the bitmap image to the number of output tones of the printer engine 117.

In this manner, the bitmap image which is stored in the band buffer 109 for respective bands and color components is output to the printer engine 117, thus forming a color image on a printing medium.

A density corrector 115 controls the scanner 116 to scan a tone patch pattern (to be described later) via an I/F 118 as a serial bus interface such as USB, IEEE1394, or the like to obtain the image data of the tone patch pattern. The density corrector 115 creates a density correction table 113b based on the density values of respective patches, and stores the density correction table 113b in a predetermined area of the RAM 113. Also, the density corrector 115 controls the scanner 116 to scan a mixed patch pattern (to be described later), creates a basic color density correction table 113c on the basis of the density values of respective patches and the basic color density characteristic table 111c, and stores the basic color density correction table 113c in a predetermined area of the RAM 113.

[Color Conversion Table]

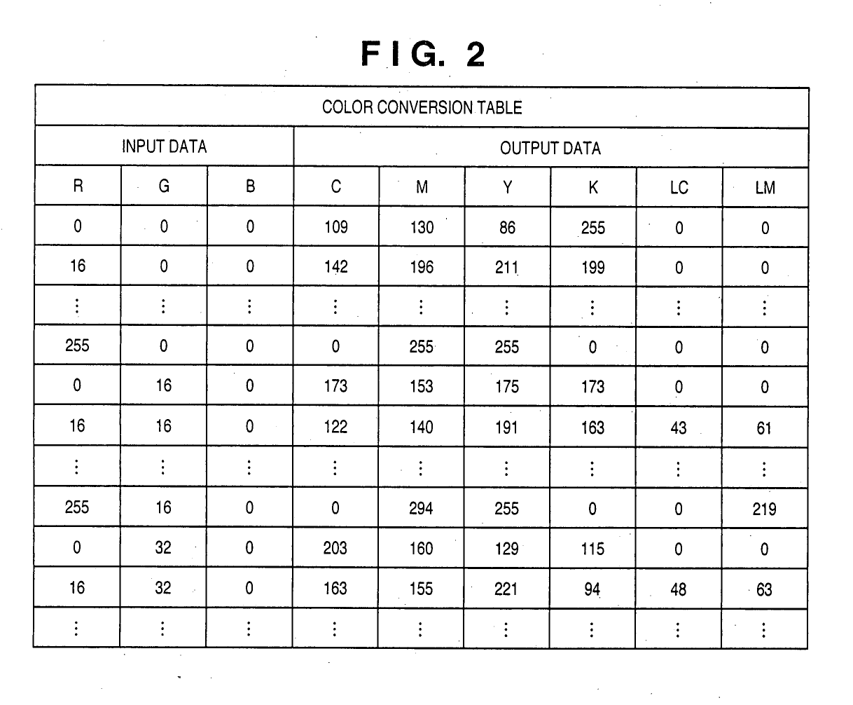

FIG. 2 is a view for explaining the color conversion table 111b.

The color conversion table 111b is used to associate R, G, and B image data input to the printer 102 and color component data C, M, Y, K, LC, and LM corresponding to six color toners. The color conversion table 111b is an RGB three-dimensional lookup table (3DLUT) having output values at given intervals with respect to R, G, and B data. Note that the data corrector 114 calculates an output value corresponding to an input value which is not prepared in the color conversion table 111b by interpolation of output values corresponding to input values around that input value.

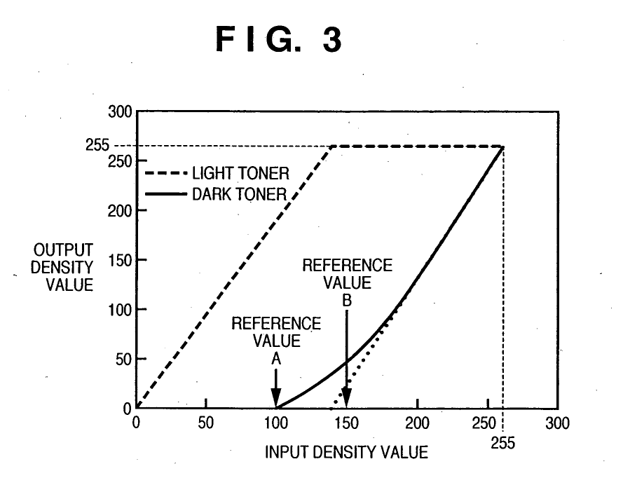

FIG. 3 shows a state wherein the density levels before and after color conversion of a cyan (C) region as a basic color are extracted from the color conversion table 111b. Note that R, G, and B data input to the color conversion table 111b indicate luminance values, but FIG. 3 indicates the relationship between the input and output density values for the sake of simplicity. Note that these six colors C, M, Y, K, LC, and LM are primary colors. Also, colors formed by cyan (C) and light cyan (LC) are defined as basic colors (the same applies to colors formed by mixing magenta (M) and light magenta (LM)).

As shown in FIG. 3, only light toner is used in a region wherein the input density value of cyan (C) is low, and when a reference density value (reference value B shown in FIG. 3) is reached, a cyan (C) region is reproduced by beginning to use dark toner.

As will be described in detail later, the basic color density correction table 113c is created to begin to use the dark toner from reference value A, and then to use it from reference value B based on the color conversion table 111b, so as to fully utilize density correction of the first embodiment.

[Color Processing]

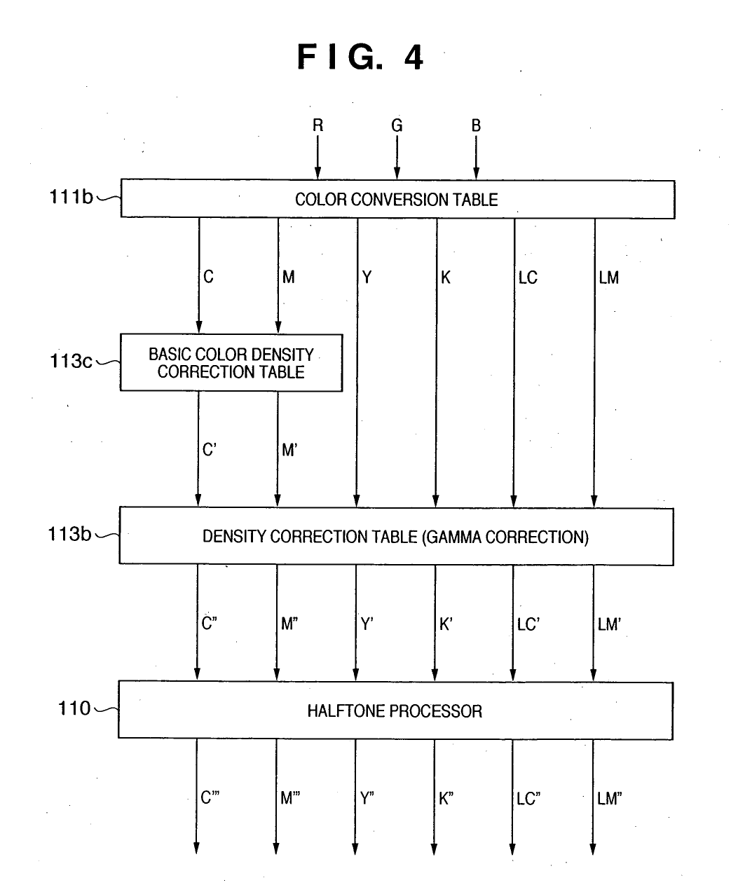

FIG. 4 is a chart for explaining color processing to be executed by the image processor 103.

Color signal values R, G, and B of input image data are converted into signal values of six colors C, M, Y, K, LC, and LM by the color conversion table 111b (3DLUT). Of the signal values of the six colors, those of two colors C and M are corrected by the basic color density correction table 113c (1DLUT), and the signal values of the six colors C′, M′, Y, K, LC, and LM are then corrected by the density correction table 113b (gamma LUT). The gamma-corrected signals of the six colors C″, M″, Y′, K′, LC′, and LM′ undergo error diffusion by the halftone processor 110 to be converted into signal values C′″, M′″, Y″, K″, LC″, and LM″, the number of tones of which is dropped.

[Tone Patch Pattern]

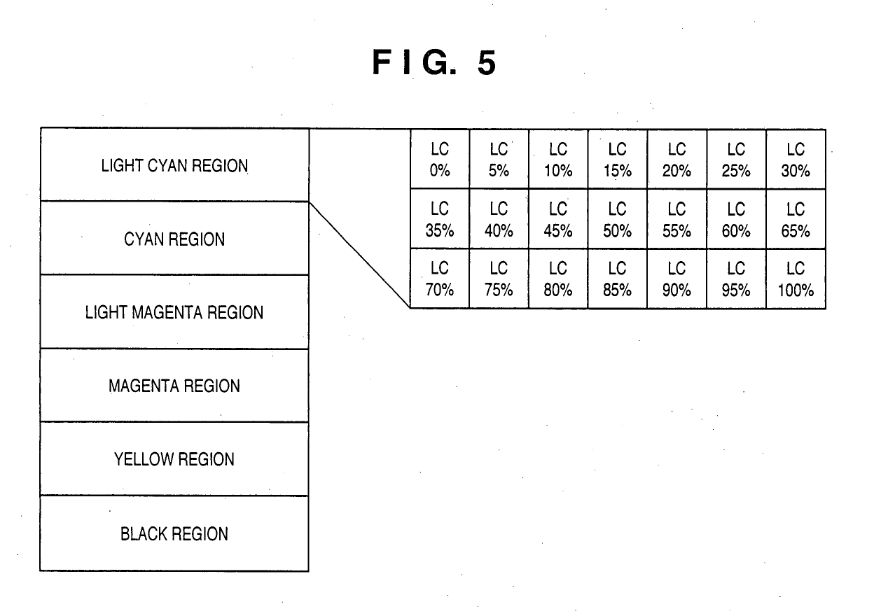

FIG. 5 shows the tone patch pattern used to create the density correction table 113b.

The tone patch pattern has color regions LC, C, LM, M, Y, and K, and patches whose density levels change at 5% steps are arranged on each region. This tone patch pattern is printed on a print sheet in accordance with a command of the host computer 101 or a test print function of the printer 102. Note that the density corrector 115 obtains the tone characteristics of the primary colors (C, M, Y, K, LC, and LM) from image data obtained by scanning the tone patch pattern, and creates the density correction table 113b that converts the tone characteristics of the primary colors into linear characteristics. Note that the density step value of patches is not limited to 5%, but other density step values may be used as long as patches that suffice to obtain the tone characteristics of the primary colors can be formed.

[Mixed Patch Pattern]

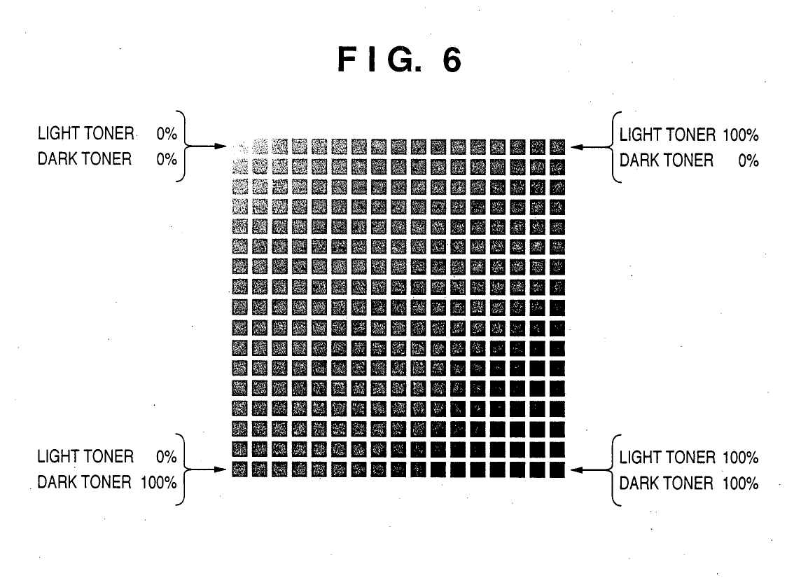

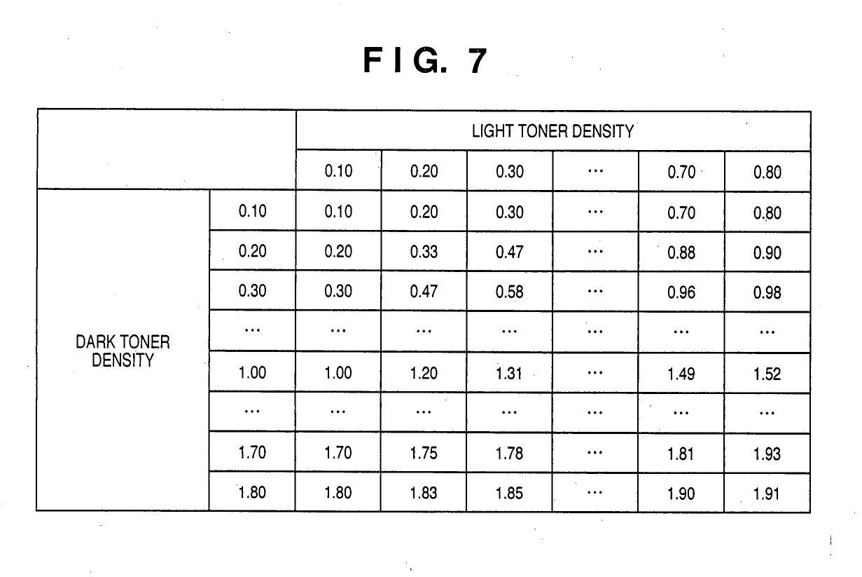

FIG. 6 shows the mixed patch pattern used to create the basic color density characteristic table 111c, and FIG. 7 shows an example of the basic color density characteristic table 111c indicating the relationship the mixed ratios and density values of dark and light toners.

The mixed patch pattern is obtained by extracting 17 samples of density values (0 to 100%) of light and dark toners of the basic colors, and printing unicolors of these 17 samples and combinations of mixed colors of these 17 samples on a print sheet. By two-dimensionally mapping density values obtained by measuring the mixed patch pattern by the scanner 116 (or a calorimeter or the like), the basic color density characteristic table, 111c is obtained. Note that the mixed patch pattern and basic color density characteristic table 111c must be prepared for each of combinations of dark and light toners with the same hue value. Therefore, in the six-color system of the first embodiment, the mixed patch pattern and basic color density characteristic table 111c are created for each of a combination of C and LC, and that of M and LM. In a seven-color system having light yellow (LY), the mixed patch pattern and basic color density characteristic table 111c are further created for a combination of Y and LY.

The basic color density characteristic table 111c has density values (input values) of dark and light toners at arbitrary intervals. For this reason, the density corrector 115 calculates an output value corresponding to an input value, which is not prepared, by linear interpolation of output values corresponding to input values around that input value.

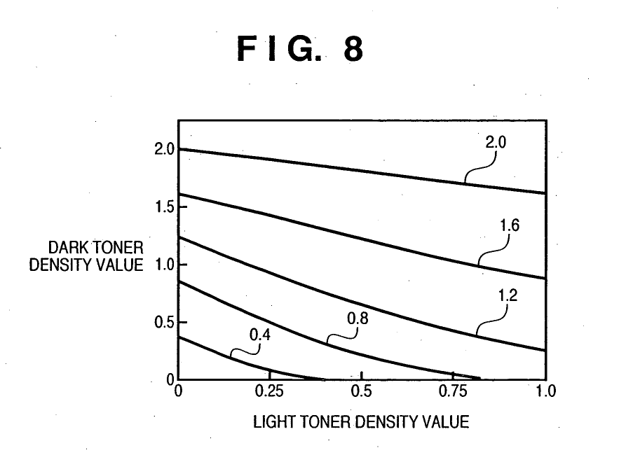

FIG. 8 shows equal density curves in 0.4-density value increments from the basic color density characteristic table 111c using linear interpolation.

[Calibration]

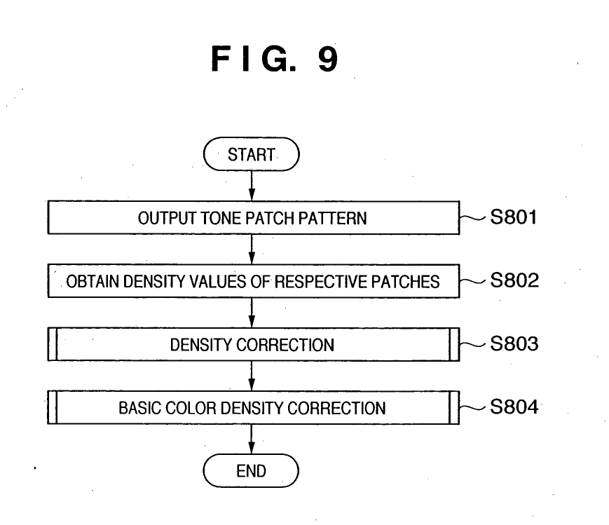

FIG. 9 is a flowchart for explaining calibration of the printer 102. This flow is implemented when the CPU 112 of the image processor 103 executes a program stored in the ROM 111.

The tone patch pattern shown in FIG. 5 is printed on the basis of a user's instruction or the like (S801), and is scanned by the scanner 116. As a result, the density values of patches are obtained (S802), density correction table (to be described later) is generated using the density values of the patches (S803), and basic color density correction table (to be described later) is then generated (S804).

Density Correction

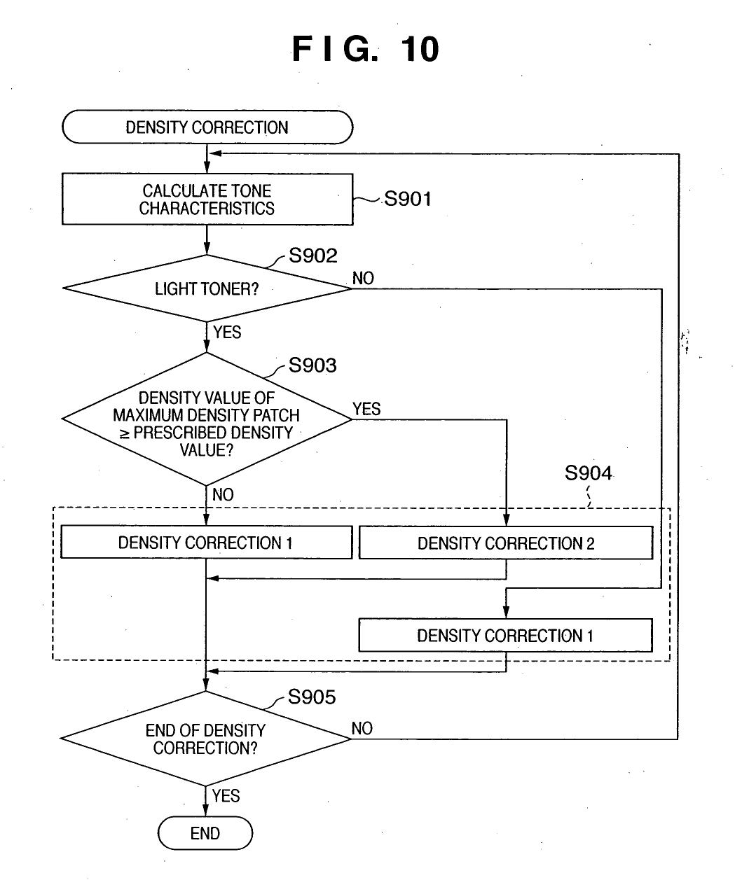

FIG. 10 is a flowchart showing details of the density correction (S803). This processing is also executed by the CPU 112.

The density characteristics (tone characteristics) corresponding to the input density levels upon creating the tone patch pattern are calculated using the density values of the patches for each color region shown in FIG. 5 (S901), and it is checked if the tone characteristics of interest are those of light toner (S902). If the tone characteristics of interest are those of light toner, it is checked if the density value of a patch with a maximum density is equal to or higher than a predetermined density value (S903). If the density value of the patch with the maximum density is equal to or higher than the prescribed density value, density correction 2 is executed; otherwise, density correction 1 is executed (S904). On the other hand, if the tone characteristics of interest are those of dark toner, density correction 1 is executed (S904). The above processing is repeated for the tone characteristics of all the color regions of the tone patch pattern based on the decision in step S905.

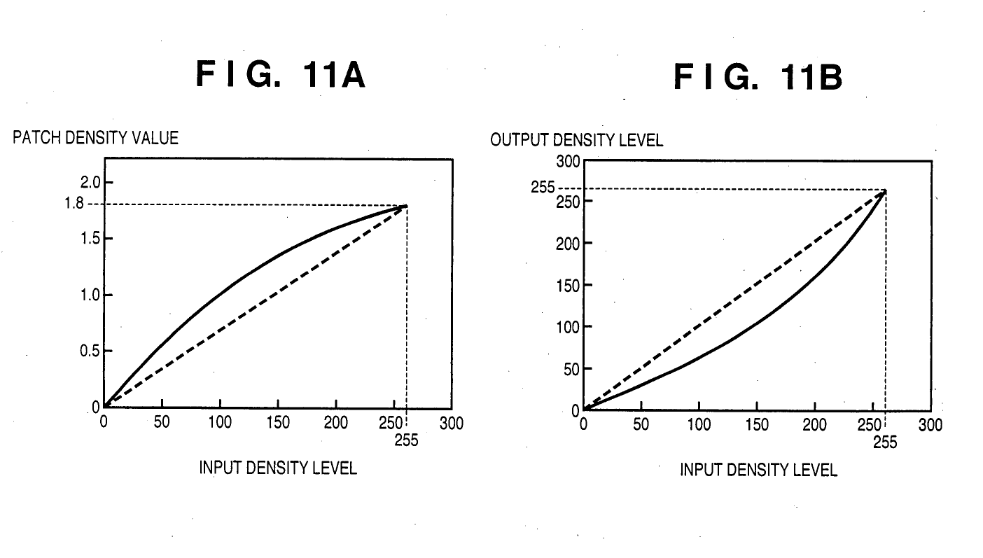

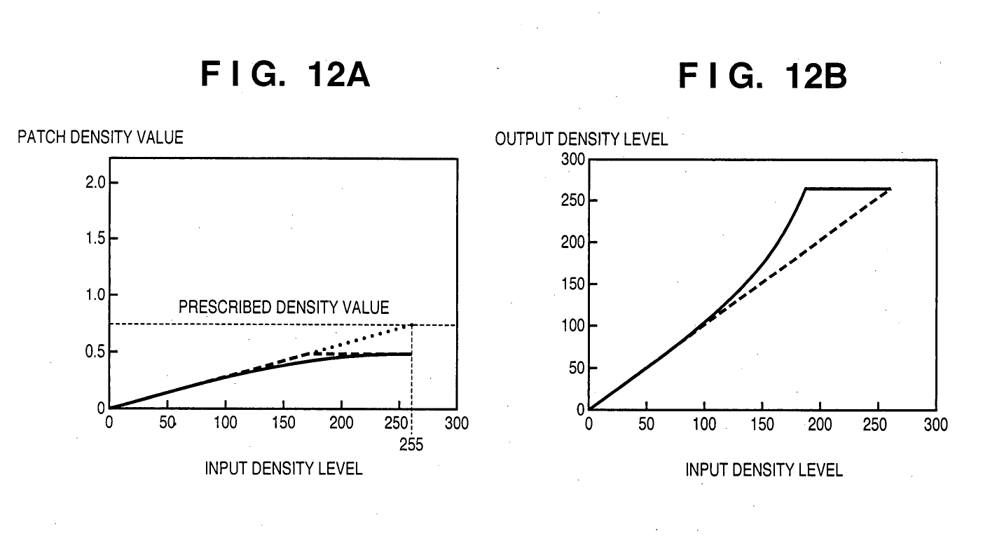

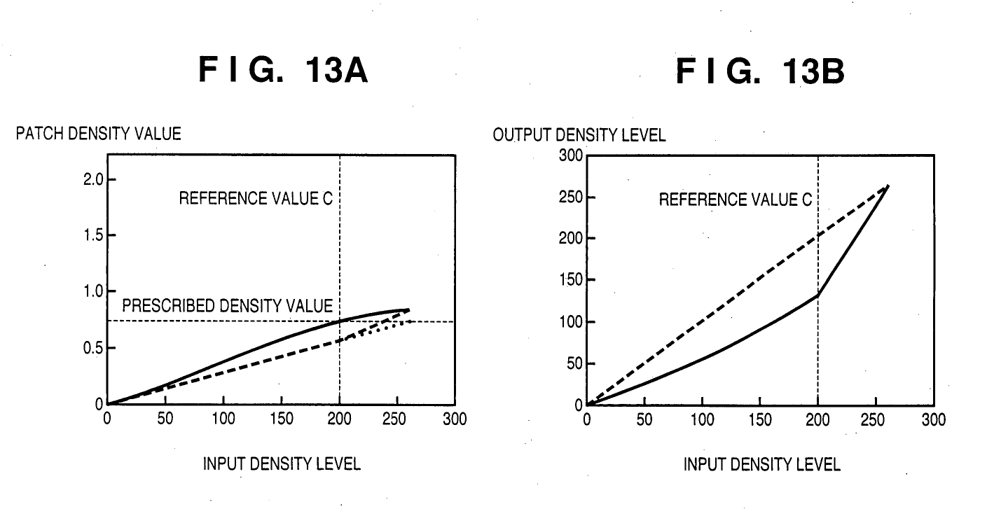

FIG. 11A shows an example of the density characteristics of dark toner, and FIG. 11B shows an example of the density correction table. FIG. 12A shows an example of the density characteristics of light toner, and FIG. 12B shows an example of the density correction table when the density value of a patch with a maximum density is less than a prescribed density value. FIG. 13A shows an example of the density characteristics of light toner, and FIG. 13B shows an example of the density correction table when a maximum measured density value of the light toner exceeds the prescribed density value.

Note that the measurement result of the tone characteristics normally does not start from zero density value but starts from the background density due to the density of the face of a print sheet and attachment of toner owing to contamination of the interior of the printer engine 117. FIGS. 11A, 12A, and 13A show the tone characteristics after this background density is corrected. That is, in all the tone characteristics shown in this embodiment, the background density is corrected.

Density correction processes 1 and 2 will be described below with reference to FIGS. 11A to 13B. Note that the density correction process in FIGS. 11A and 11B and FIGS. 12A and 12B corresponds to density correction 1, and that in FIGS. 13A and 13B corresponds to density correction 2.

The solid curve shown in FIG. 11A indicates the measurement result of the tone characteristics of dark toner, and the broken line indicates prescribed tone characteristics (linear characteristics). Therefore, in order to correct the tone characteristics indicated by the solid curve to the linear characteristics indicated by the broken line, a density correction table 113b having correction characteristics indicated by the solid curve in FIG. 11B is created.

The solid curve shown in FIG. 12A indicates the measurement result of the tone characteristics of light toner. In this case, since the density value of a patch with a maximum density does not reach a prescribed density value, tone characteristics, which define a density value range up to a reproducible density value by predetermined linear characteristics, and the subsequent range by flat characteristics, are defined, as indicated by the broken curve. When the linear portion is extended, the prescribed density value is reached at the input density level=255, as indicated by the dotted line. Therefore, in order to correct the tone characteristics indicated by the solid curve to the prescribed tone characteristics indicated by the broken curve, a density correction table 113b having correction characteristics indicated by the solid curve in FIG. 12B is created.

The solid curve shown in FIG. 13A indicates the measurement result of the tone characteristics of light toner. In this case, since the density value of a patch with a maximum density exceeds the prescribed density value, tone characteristics, which define a density value range up to an input density level (reference value C), where the tone characteristics reach the prescribed density value, by predetermined linear characteristics, and the range after reference value C by characteristics toward the density value of the patch with the maximum density, are defined, as indicated by the broken curve. By extending the linear portion before reference value C, the prescribed density value is reached at the input density level=255, as indicated by the dotted line. Therefore, in order to correct the tone characteristics indicated by the solid curve to the prescribed tone characteristics indicated by the broken curve, a density correction table 113b having correction characteristics indicated by the solid curve in FIG. 13B is created.

Basic Color Density Correction

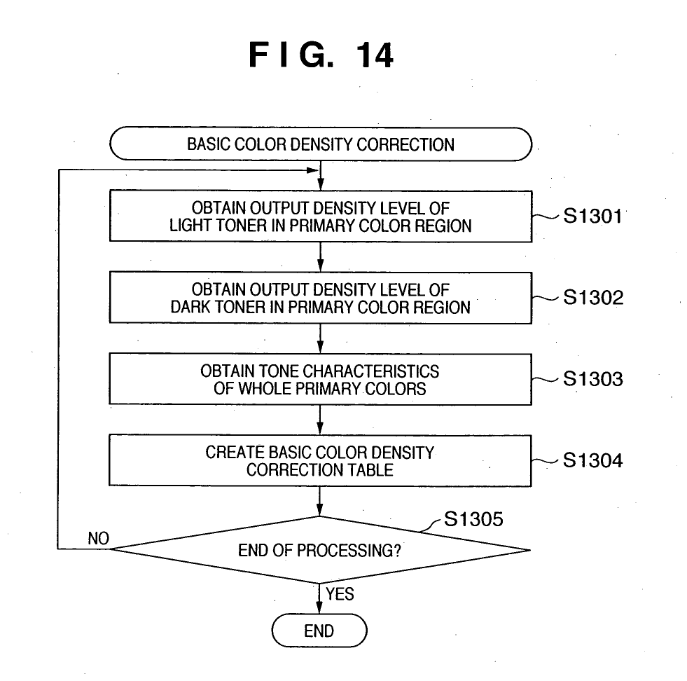

FIG. 14 is a flowchart showing details of basic color density correction (S804). This flow is implemented when the CPU 112 of the image processor 103 executes a program stored in the ROM 111.

The input density levels of the light and dark toners in the primary color region after color conversion are obtained from the color conversion table 111b, and are input to the density correction tables 113b created in the density correction process (S803), thus obtaining the output density levels of the light and dark toners in the primary color region (S1301, S1302).

The tone characteristics of the whole basic color region including the mixed color region of the light and dark toners are obtained from the region of only the light toner on the basis of the output density levels of the light and dark toners in the primary color region with reference to the basic color density characteristic table 111c (S1303). As a result, the tone characteristics of the whole primary colors including the mixed color region of the dark and light toners are obtained.

Next, the basic color density correction table 113c which converts the tone characteristics of the whole primary colors into prescribed primary color tone characteristics is created with reference to the basic color density characteristic table 111c (S1304).

The above processing is repeated for all combinations (those of LC and C, and LM and M in this embodiment) of light and dark toners with the same hue values based on the decision in step S1305.

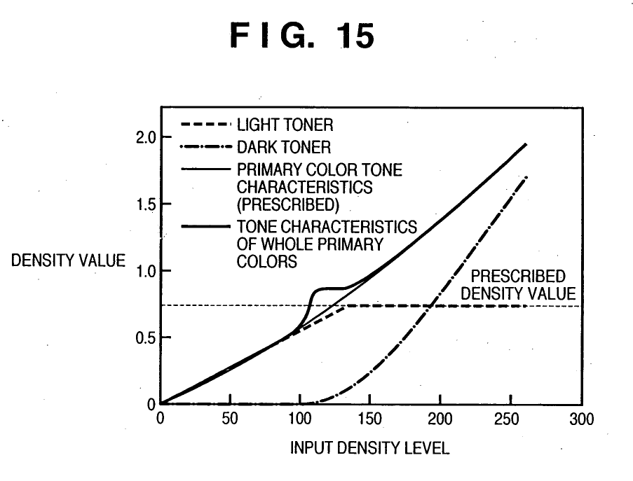

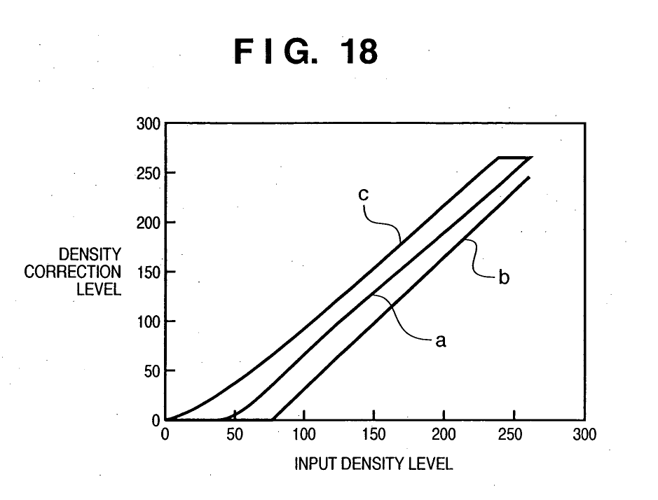

FIGS. 15 to 17 show examples of the tone characteristics of the dark and light toners in the primary color region, those of the whole primary colors reproduced by the dark and light toners, and prescribed primary color tone characteristics. FIG. 18 shows an example of the basic color density correction table 113c created by the basic color density correction process (S804). The basic color density correction process will be described in detail below using these figures.

FIG. 15 shows examples of the tone characteristics of the dark and light toners when both the dark and light toners exhibit prescribed tone characteristics in the density correction process (S803), and the tone characteristics of the whole primary colors.

Referring to FIG. 15, for example, when the input density level is 120, a density value D_{L} of the light toner is 0.70, and a density value Dd of the dark toner is 0.25, a density value Db of the whole primary colors, which is calculated from D_{L} and Dd with reference to the basic color density characteristic table 111c, is 0.93, and a density value Dbs of the prescribed primary color tone characteristics is 0.80. In this case, a density value Dd′ (e.g., 0.10) of the dark toner is calculated with reference to the basic color density characteristic table 111c, so that Db and Dbs match without changing D_{L}.

Next, the signal level of the dark toner when the input density level is 120, i.e., the signal level that reproduces the density value Dd=0.25, is corrected to a level that reproduces the density value Dd′=0.10. Therefore, the density levels corresponding to Dd=0.25 and Dd′=0.10 of the tone characteristics (actually measured values) indicated by the solid curve in FIG. 11A are calculated, input density levels are calculated from the density correction table 113b using these density levels as the output density levels, and a correction table is created using these levels as signal levels before and after correction.

Such correction is applied to the whole primary colors to create a basic color density correction table 113c indicated by (a) in FIG. 18, thus obtaining prescribed primary color tone characteristics indicated by the thin curve in FIG. 15.

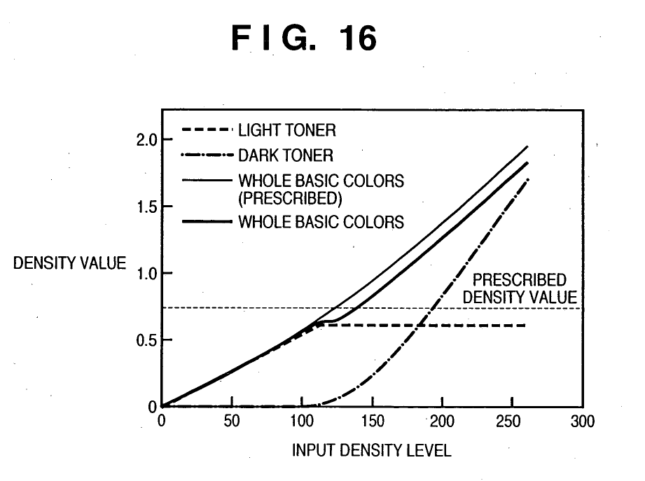

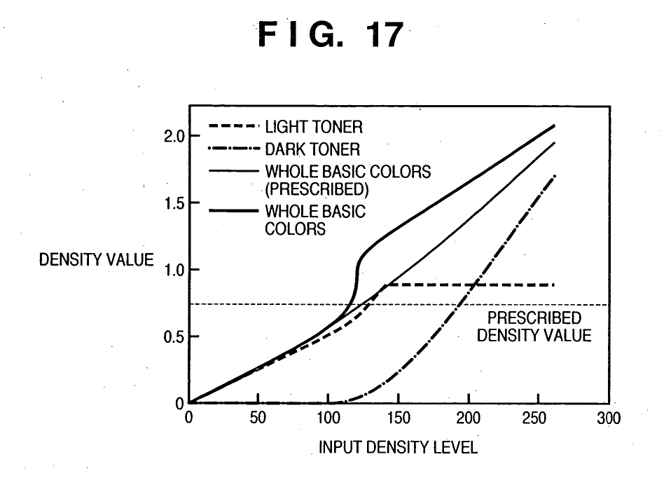

When the maximum density values of the dark and light toners are less than the prescribed density value in the density correction process (S803), as shown in FIG. 16, or when maximum density values of the dark and light toners exceed the prescribed density value in the density correction process (S803), as shown in FIG. 17, the same correction process as in the above description is also applied to the whole primary color to create a basic color density correction table 113c indicated by (b) or (c) in FIG. 18, thus obtaining prescribed primary color tone characteristics indicated by the thin curve in FIG. 16 or 17.

In this way, since the aforementioned calibration processing is executed in the six-color system, and tone correction is applied to color component signals corresponding to the dark toners of the primary colors having combinations of the dark and light toners using the basic color density correction tables 113c before gamma correction is applied to the respective color component signals, density variations in the intermediate density region (mixed color region) can be suppressed to prevent discontinuity of tone changes, and generation of pseudo-contours.

Furthermore, the tone correction of the mixed color region of the primary colors is done by the calibration including formation of the patch patterns of the primary colors and measurement of the patch densities. Hence, only a smaller number of patch patterns are required, and increases in time and consumption amount of print sheets and toners required for the calibration can be suppressed.

Since the calibration can attain the tone correction of the mixed color region based only on the patch densities of the primary colors, it can be easily implemented by the hardware arrangement equivalent to that of the four-color system, and the hardware arrangement of the four-color system can be relatively easily expanded to the six-color system.

### Second Embodiment

Image processing according to the second embodiment of the present invention will be described below. Note that the same reference numerals denote the same components as those in the first embodiment, and a detailed description thereof will be omitted.

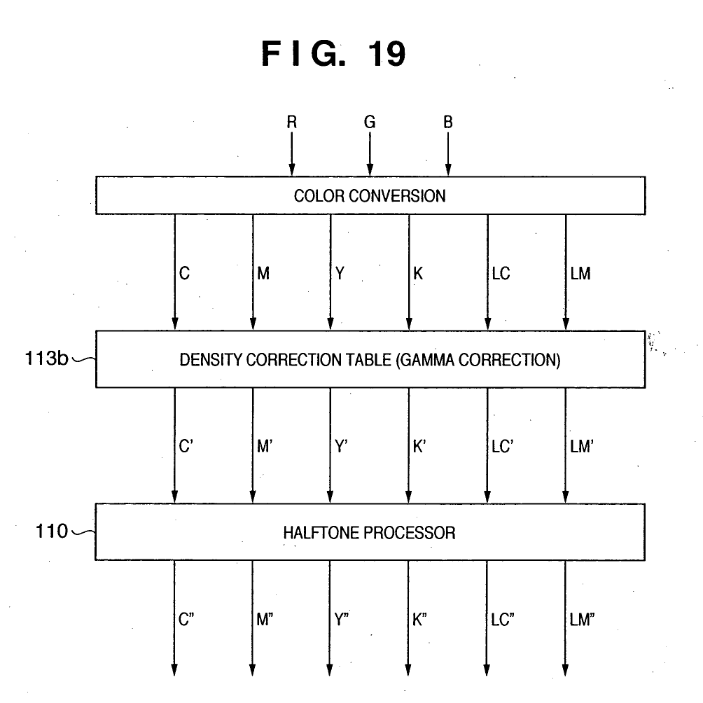

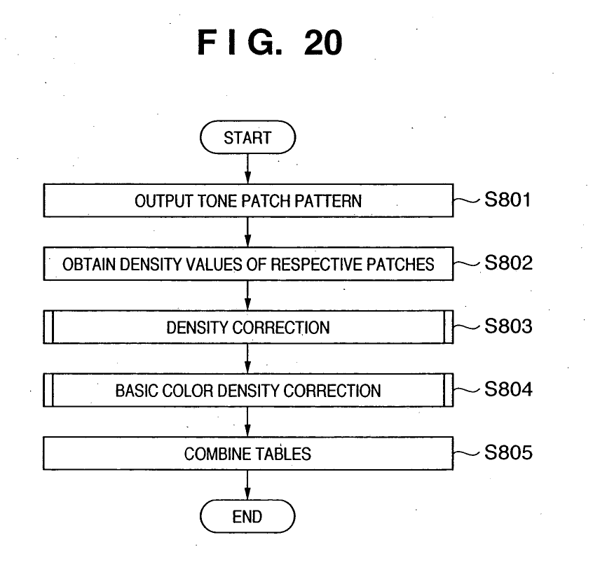

In the first embodiment, as shown in FIG. 4, color processing is done by creating the basic color density correction table 113c and density correction table 113b as independent tables. However, since both these tables are linear lookup tables, they are integrated in step S805 shown in FIG. 20 into one table (e.g., the density correction table 113b), and the color processing shown in FIG. 19 can be done using this integrated table.

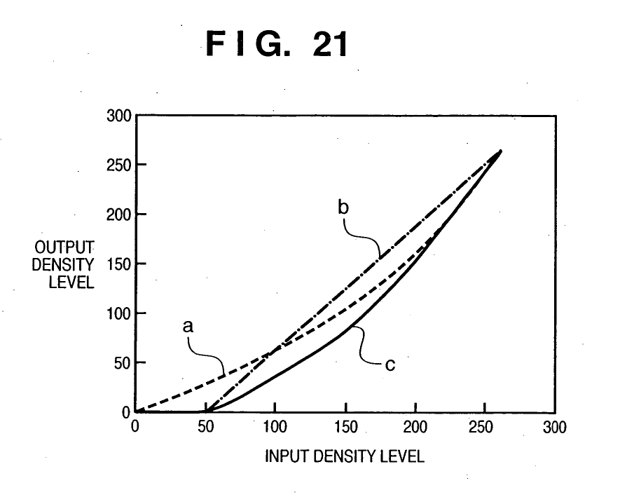

FIG. 21 shows an example of the density correction table 113b integrated with the basic color density correction table 113c. In FIG. 21, (a) indicates the density correction table 113b created in step S803, (b) indicates the basic color density correction table 113c created in step S804, and (c) indicates the integrated density correction table 113b.

Let Di be the corrected density level of the density correction table 113b and SDi be the corrected density level of the basic color density correction table 113c at a given input density level i. Then, a corrected density level Di′ of the integrated density correction table 113b at the input density level i is given by:
Di′=SD_{Di}

### Modification of Embodiment

In the above description, the primary colors which use the dark and light toners are magenta and cyan. However, the present invention is not limited to these specific colors. If yellow and black use toners which have identical hue values but different lightness values, the above tone correction and density correction can be similarly applied to these colors.

In the above example, the input image signals are R, G, and B luminance signals. Alternatively, even when C, M, and Y (or C, M, Y, and K) density signals are input, the above tone correction and density correction can be similarly applied.

In the above description, output values which are not held in the tables are calculated by linear interpolation. However, the present invention is not limited to the linear interpolation method, and other interpolation methods such as spline interpolation and the like may be used.

In the above description, the calibration for the color printer has been explained. Also, the present invention can be applied to the calibration of a color copying machine and color MFP.

In the above description, the calibration of the electrophotographic printer using toners as color recording materials has been explained. Also, the present invention is also effective for image forming apparatuses using pigment- and dye-based inks and the like.

In the above description, linear characteristics are used as the prescribed tone characteristics as targets of the density correction and basic color density correction. However, curves may be used.

### Other Embodiments

Note that the present invention can be applied to an apparatus comprising a single device or to system constituted by a plurality of devices.

Furthermore, the invention can be implemented by supplying a software program, which implements the functions of the foregoing embodiments, directly or indirectly to a system or apparatus, reading the supplied program code with a computer of the system or apparatus, and then executing the program code. In this case, so long as the system or apparatus has the functions of the program, the mode of implementation need not rely upon a program.

Accordingly, since the functions of the present invention are implemented by computer, the program code installed in the computer also implements the present invention. In other words, the claims of the present invention also cover a computer program for the purpose of implementing the functions of the present invention.

In this case, so long as the system or apparatus has the functions of the program, the program may be executed in any form, such as an object code, a program executed by an interpreter, or scrip data supplied to an operating system.

Example of storage media that can be used for supplying the program are a floppy disk, a hard disk, an optical disk, a magneto-optical disk, a CD-ROM, a CD-R, a CD-RW, a magnetic tape, a non-volatile type memory card, a ROM, and a DVD (DVD-ROM and a DVD-R).

As for the method of supplying the program, a client computer can be connected to a website on the Internet using a browser of the client computer, and the computer program of the present invention or an automatically-installable compressed file of the program can be downloaded to a recording medium such as a hard disk. Further, the program of the present invention can be supplied by dividing the program code constituting the program into a plurality of files and downloading the files from different websites. In other words, a WWW (World Wide Web) server that downloads, to multiple users, the program files that implement the functions of the present invention by computer is also covered by the claims of the present invention.

It is also possible to encrypt and store the program of the present invention on a storage medium such as a CD-ROM, distribute the storage medium to users, allow users who meet certain requirements to download decryption key information from a website via the Internet, and allow these users to decrypt the encrypted program by using the key information, whereby the program is installed in the user computer.

Besides the cases where the aforementioned functions according to the embodiments are implemented by executing the read program by computer, an operating system or the like running on the computer may perform all or a part of the actual processing so that the functions of the foregoing embodiments can be implemented by this processing.

Furthermore, after the program read from the storage medium is written to a function expansion board inserted into the computer or to a memory provided in a function expansion unit connected to the computer, a CPU or the like mounted on the function expansion board or function expansion unit performs all or a part of the actual processing so that the functions of the foregoing embodiments can be implemented by this processing.

As many apparently widely different embodiments of the present invention can be made without departing from the spirit and scope thereof, it is to be understood that the invention is not limited to the specific embodiments thereof except as defined in the appended claims.

### CLAIM OF PRIORITY

This application claims priority from Japanese Patent Application No. 2004-275030 filed on Sep. 22, 2004, the entire contents of which are hereby incorporated by reference herein.

What is claimed is:

1. An image processing apparatus using dark and light color recording materials which have a similar hue value but different lightness values, said apparatus comprising:
an obtainer, arranged to obtain tone characteristics of respective colors from a patch pattern of respective color recording materials;
a tone corrector, arranged to create a tone correction table used to correct the tone characteristics of the respective colors on the basis of the tone characteristics of the respective colors; and
a density corrector, arranged to create a density correction table for correcting the tone character of basic color generated by referring to the tone correction tables, and a character table, wherein each table indicates a density character of mixture colors mixed the dark and light color recording materials,
wherein the tone character of the basic colors, which include a primary color formed by the dark color recording material, a primary color formed by the light color recording material, and the mixture colors, are calculated by referring to the character tables.

2. The apparatus according to claim 1, further comprising a color processor arranged to apply color processing to color signals corresponding to the color recording materials using the density correction table and the tone correction table.

3. The apparatus according to claim 1, further comprising:
an integrator, arranged to create a correction table obtained by integrating the density correction table and the tone correction table; and
a color processor arranged to apply color processing to color signals corresponding to the color recording materials using the correction table.

4. The apparatus according to claim 3, wherein said color processor corrects levels of the color signals corresponding to the dark color recording materials using the correction table.

5. The apparatus according to claim 1, wherein said tone corrector creates the tone correction table used to obtain tone characteristics which define predetermined linear characteristics until a reachable density value, and flat characteristics after the reachable density value, for the light color recording material whose density value of the patch does not reach a prescribed density value.

6. The apparatus according to claim 1, wherein said tone corrector creates the tone correction table used to obtain tone characteristics which define predetermined linear characteristics until a level of a color signal that reaches a prescribed density value, and characteristics toward a maximum density value of the patch after the linear characteristics, for the light color recording material whose density value of the patch exceeds the prescribed density value.

7. The apparatus according to claim 1, wherein the characteristic table is obtained in advance from a patch pattern formed by mixing the dark and light color recording materials.

8. A method of calibrating an image processing apparatus using dark and light color recording materials which have a similar hue value but different lightness values, said method comprising the steps of:
obtaining tone characteristics of respective colors from a patch pattern of respective color recording materials;
creating a tone correction table used to correct the tone characteristics of the respective colors on the basis of the tone characteristics of the respective colors; and
creating a density correction table for correcting the tone character of basic color generated by referring to the tone correction tables, and a character table, wherein each table indicates a density character of mixture colors mixed the dark and-light color recording materials,
wherein the tone character of the basic colors, which include a primary color formed by the dark color recording material, a primary color formed by the light color recording material, and the mixture colors, are calculated by referring to the character tables.

9. The method according to claim 8, further comprising the step of applying color processing to color signals corresponding to the color recording materials using the density correction table and the tone correction table.

10. The method according to claim 8, further comprising the steps of:
creating a correction table obtained by integrating the density correction table and the tone correction table; and
applying color processing to color signals corresponding to the color recording materials using the correction table.

11. The method according to claim 10, wherein levels of the color signals corresponding to the dark color recording materials are corrected using the correction table.

12. The method according to claim 8, wherein the tone correction table used to obtain tone characteristics which define predetermined linear characteristics until a reachable density value, and flat characteristics after the reachable density value is created, for the light color recording material whose density value of the patch does not reach a prescribed density value.

13. The method according to claim 8, wherein the tone correction table used to obtain tone characteristics which define predetermined linear characteristics until a level of a color signal that reaches a prescribed density value, and characteristics toward a maximum density value of the patch after the linear characteristics is created, for the light color recording material whose density value of the patch exceeds the prescribed density value.

14. The method according to claim 8, wherein the characteristic table is obtained in advance from a patch pattern formed by mixing the dark and light color recording materials.

15. An image processing method of an image processing apparatus using dark and light color recording materials that form colors having same hue and different brightness, said method comprising the step of performing color processing on color signals correspond to color recording materials using tone correction tables and density correction tables,
wherein the tone correction tables for correcting tone characters of colors are generated based on the tone characters of the colors obtained from patch patterns, each of which is formed by each color recording material,
wherein the density correction tables for correcting tone characters of basic colors are generated referring to the tone correction tables, and character tables, each of which indicates a density character of mixture colors mixed the dark and light color recording materials, and
wherein the tone character of the basic colors, each of which includes a primary color formed by the dark color recording material, a primary color formed by the light color recording material, and the mixture colors, are calculated referring to the character tables.

16. The method according to claim 15, further comprising the step of creating a correction table obtained by integrating the density correction table and the tone correction table.

17. The method according to claim 16, wherein levels of the color signals corresponding to the dark color recording materials are corrected using the correction table.

18. The method according to claim 15, wherein the tone correction table used to obtain tone characteristics which define predetermined linear characteristics until a reachable density value, and flat characteristics after the reachable density value is created for the light color recording material whose density value of the patch does not reach a prescribed density value.

19. The method according to claim 15, wherein the tone correction table used to obtain tone characteristics which define predetermined linear characteristics until a level of a color signal that reaches a prescribed density value, and characteristics toward a maximum density value of the patch after the linear characteristics is created for the light color recording material whose density value of the patch exceeds the prescribed density value.

20. The method according to claim 15, wherein the characteristic table is obtained in advance from a patch pattern formed by mixing the dark and light color recording materials.

21. A computer program for a method of calibrating an image processing apparatus using dark and light color recording materials which have a similar hue value but different lightness values, said method comprising the steps of:
obtaining tone characteristics of respective colors from a patch pattern of respective color recording materials;
creating a tone correction table used to correct the tone characteristics of the respective colors on the basis of the tone characteristics of the respective colors; and
creating a density correction table for correcting the tone character of basic color generated by referring to the tone correction tables, and a character table, wherein each table indicates a density character of mixture colors mixed the dark and light color recording materials, and
wherein the tone character of the basic colors, which include a primary color formed by the dark color recording material, a primary color formed by the light color recording material, and the mixture colors, are calculated by referring to the character tables.

22. A computer program product stored on a computer readable medium comprising program code for executing a calibration of an image processing apparatus using dark and light color recording materials which have a similar hue value but different lightness values, said calibration comprising the steps of:
obtaining tone characteristics of respective colors from a patch pattern of respective color recording materials;
creating a tone correction table used to correct the tone characteristics of the respective colors on the basis of the tone characteristics of the respective colors; and
creating a density correction table for correcting the tone character of basic color are generated by referring to the tone correction tables, and a character table, wherein each table indicates a density character of mixture colors mixed the dark and light color recording materials,
wherein the tone character of the basic colors, which include a primary color formed by the dark color recording material, a primary color formed by the light color recording material, and the mixture colors, are calculated by referring to the character tables.

23. A computer program for an image processing method of an image processing apparatus using dark and light color recording materials that form colors having same hue and different brightness, said method comprising the step of performing color processing on color signals correspond to color recording materials using tone correction tables and density correction tables,
wherein the tone correction tables for correcting tone characters of colors are generated based on the tone characters of the colors obtained from patch patterns, each of which is formed by each color recording material,
wherein the density correction tables for correcting tone characters of basic colors are generated referring to the tone correction tables, and character tables, each of which indicates a density character of mixture colors mixed the dark and light color recording materials, and
wherein the tone character of the basic colors, each of which includes a primary color formed by the dark color recording material, a primary color formed by the light color recording material, and the mixture colors, are calculated referring to the character tables.

24. A computer program product stored on a computer readable medium comprising program code for executing an image processing method of an image processing apparatus using dark and light color recording materials that form colors having same hue and different brightness, said method comprising the step of performing color processing on color signals correspond to color recording materials using tone correction tables and density correction tables,
wherein the tone correction tables for correcting tone characters of colors are generated based on the tone characters of the colors obtained from patch patterns, each of which is formed by each color recording material,
wherein the density correction tables for correcting tone characters of basic colors are generated referring to the tone correction tables, and character tables, each of which indicates a density character of mixture colors mixed the dark and light color recording materials, and
wherein the tone character of the basic colors, each of which includes a primary color formed by the dark color recording material, a primary color formed by the light color recording material, and the mixture colors, are calculated referring to the character tables.

25. An image processing method for an image processing apparatus which generates tone correction data corresponding to dark and light color recording materials by using tone patches of the dark and light color recording materials, and executes tone correction using the tone correction data, said method comprising the step of correcting representation character in a density region mixed the dark and light color recording materials from density information of mixtures mixed with the dark and light color recording materials at a plurality of levels.

26. An image processing apparatus using dark and light color recording materials which have a similar hue value but different lightness values, said apparatus comprising:
an obtainer, arranged to obtain tone characteristics of respective colors from a patch pattern of respective color recording materials;
a tone corrector, arranged to create a tone correction table used to correct the tone characteristics of the respective colors on the basis of the tone characteristics of the respective colors; and
a density corrector, arranged to create a density correction table used to correct primary colors formed by the dark color recording materials, primary colors formed by the light color recording materials, and basic colors including mixed colors of the dark and light color recording materials with reference to a characteristic table indicating density characteristics when the dark and light color recording materials are mixed and the tone correction table.
